(19) United States
(12) Patent Application Publication
(10) Pub. No.: US 2024/0186209 A1
(43) Pub. Date: Jun. 6, 2024

(54) SEMICONDUCTOR PACKAGE STRUCTURE

(71) Applicant: MEDIATEK INC., Hsinchu City (TW)

(72) Inventors: Tai-Hao PENG, Hsinchu City (TW); Yao-Tsung HUANG, Hsinchu City (TW)

(21) Appl. No.: 18/499,383

(22) Filed: Nov. 1, 2023

Related U.S. Application Data
(60) Provisional application No. 63/385,636, filed on Dec. 1, 2022.

(51) Int. Cl. H01L 23/367; H01L 23/00; H01L 23/31; H01L 23/498

(52) U.S. Cl. CPC H01L 23/367; H01L 23/3128; H01L 23/49811; H01L 23/49822; H01L 24/16; H01L 25/105; H01L 2224/16227

(57) ABSTRACT

A semiconductor package structure includes a substrate, a semiconductor die, a molding material, an interposer, and a thermal via. The substrate has a wiring structure. The semiconductor die is disposed over the substrate and is electrically coupled to the wiring structure. The molding material surrounds the semiconductor die. The interposer is disposed over the semiconductor die. The thermal via is disposed in the interposer and extends to a bottom surface of the interposer. The thermal via vertically overlaps the semiconductor die.

### CROSS REFERENCE TO RELATED APPLICATIONS

This application claims the benefit of U.S. Provisional Application No. 63/385,636 filed on Dec. 1, 2022, the entirety of which is incorporated by reference herein.

### BACKGROUND OF THE INVENTION

### Field of the Invention

The present invention relates to semiconductor technology, and, in particular, to a semiconductor package structure including a thermal via.

### Description of the Related Art

In addition to providing a semiconductor die with protection from environmental contaminants, a semiconductor package structure can also provide an electrical connection between the semiconductor die packaged inside it and a substrate such as a printed circuit board (PCB).

Although existing semiconductor package structures generally meet requirements, they have not been satisfactory in all respects. Heat is generated during operation of the semiconductor die. If the heat is not adequately removed, the increased temperature may result in damage to the semiconductor components. However, with the increase in demand for smaller devices that can perform more functions, the thermal management of semiconductor package structures has become increasingly difficult. Therefore, further improvements in semiconductor package structures are required.

### BRIEF SUMMARY OF THE INVENTION

Semiconductor package structures are provided. An exemplary embodiment of a semiconductor package structure includes a substrate, a semiconductor die, a molding material, an interposer, and a thermal via. The substrate has a wiring structure. The semiconductor die is disposed over the substrate and is electrically coupled to the wiring structure. The molding material surrounds the semiconductor die. The interposer is disposed over the semiconductor die. The thermal via is disposed in the interposer and extends to a bottom surface of the interposer. The thermal via vertically overlaps the semiconductor die.

Another embodiment of a semiconductor package structure includes a first redistribution layer, a semiconductor die, a second redistribution layer, and a thermal via. The semiconductor die is disposed over the first redistribution layer. The second redistribution layer is disposed over the semiconductor die. The thermal via is disposed in the second redistribution layer and extends to a bottom surface of the second redistribution layer. The thermal via vertically overlaps the semiconductor die.

Yet another embodiment of a semiconductor package structure includes a first redistribution layer, a semiconductor die, a conductive structure, a second redistribution layer, and a plurality of thermal vias. The substrate semiconductor die is disposed over the first redistribution layer. The conductive structure electrically couples the semiconductor die to the first redistribution layer. The second redistribution layer is disposed over the semiconductor die. The thermal vias are embedded in the second redistribution layer and are in contact with the semiconductor die.

### BRIEF DESCRIPTION OF THE DRAWINGS

The present invention can be more fully understood by reading the subsequent detailed description and examples with references made to the accompanying drawings, wherein:

FIGS. 1A-1E are cross-sectional views of various stages of manufacturing an exemplary semiconductor package structure in accordance with some embodiments of the present disclosure;

FIG. 2 is a perspective view of a portion of an exemplary semiconductor package structure in accordance with some embodiments of the present disclosure;

FIG. 3 is a cross-sectional view of an exemplary semiconductor package structure in accordance with some embodiments of the present disclosure;

FIGS. 4A-4F are cross-sectional views of various stages of manufacturing an exemplary semiconductor package structure in accordance with some embodiments of the present disclosure;

FIG. 5 is a cross-sectional view of an exemplary semiconductor package structure in accordance with some embodiments of the present disclosure; and

FIGS. 6A-6E are cross-sectional views of various stages of manufacturing an exemplary semiconductor package structure in accordance with some embodiments of the present disclosure.

### DETAILED DESCRIPTION OF THE INVENTION

The following description is made for the purpose of illustrating the general principles of the invention and should not be taken in a limiting sense. The scope of the invention is best determined by reference to the appended claims.

The present disclosure will be described with respect to particular embodiments and with reference to certain drawings, but the disclosure is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the disclosure.

Additional elements may be added on the basis of the embodiments described below. For example, the description of “a first element on/over a second element” may include embodiments in which the first element is in direct contact with the second element, and may also include embodiments in which additional elements are disposed between the first element and the second element such that the first element and the second element are not in direct contact.

The spatially relative descriptors of the first element and the second element may change as the structure is operated or used in different orientations. In addition, the present disclosure may repeat reference numerals and/or letters in the various embodiments. This repetition is for simplicity and clarity and does not in itself dictate a relationship between the various embodiments discussed.

A semiconductor package structure including a thermal via is described in accordance with some embodiments of the present disclosure. The thermal via is coupled to a semiconductor die to provide additional thermal dissipation paths, thereby enhancing efficiency of thermal dissipation.

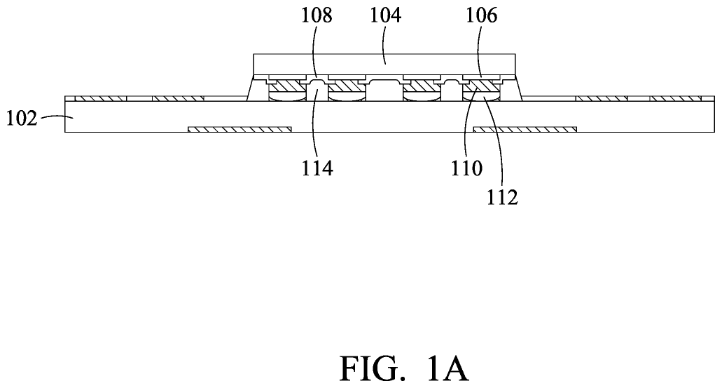

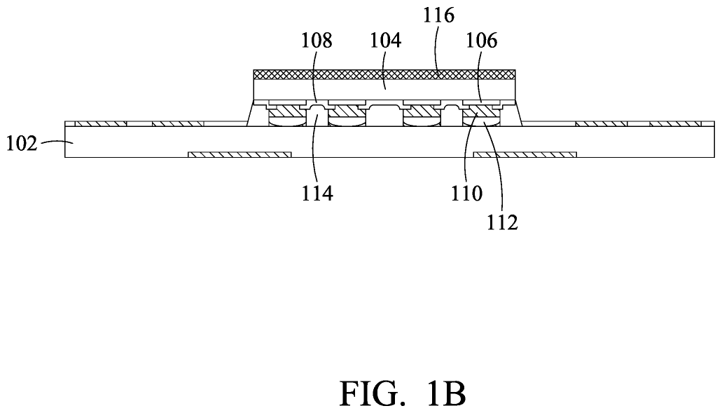

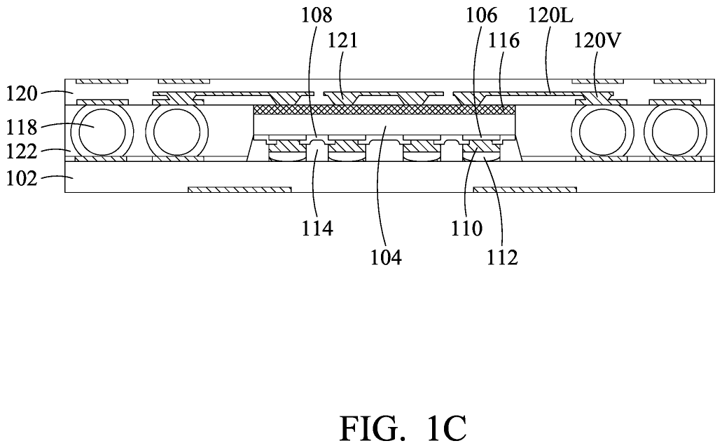

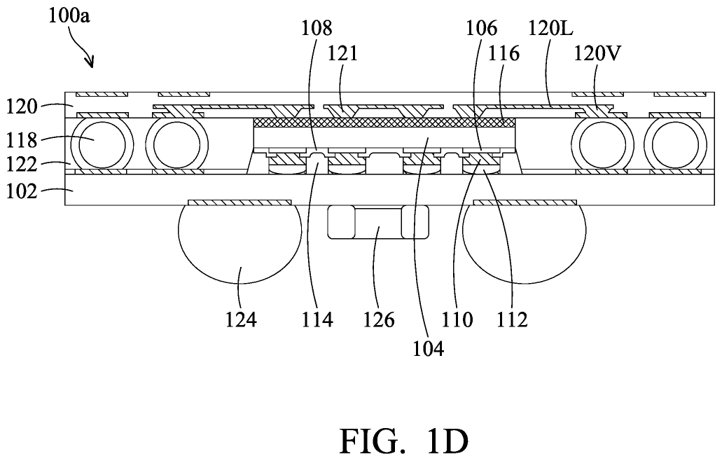

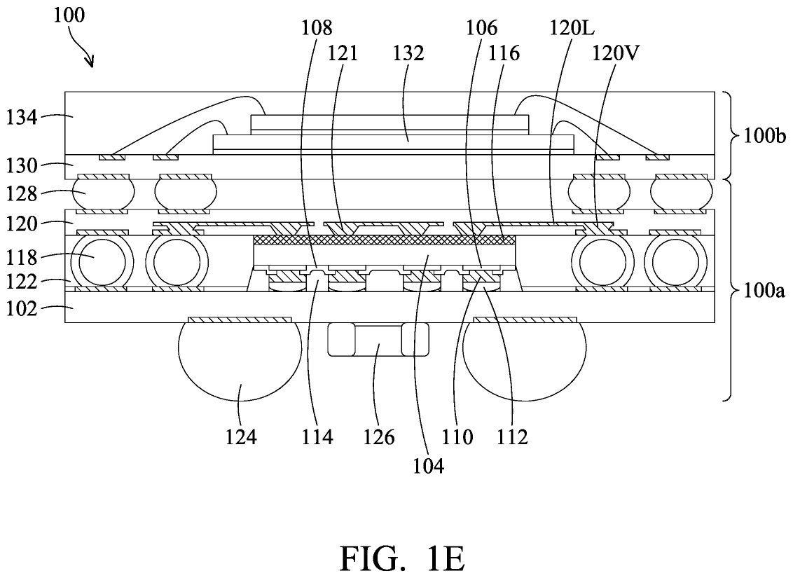

FIGS. 1A-1E are cross-sectional views of various stages of manufacturing a semiconductor package structure 100 in accordance with some embodiments of the present disclosure. Additional features can be added to the semiconductor package structure 100. Some of the features described below can be replaced or eliminated for different embodiments. To simplify the diagram, only a portion of the semiconductor package structure 100 is illustrated.

As illustrated in FIG. 1A, a substrate 102 is provided, in accordance with some embodiments. The substrate 102 may have a wiring structure. In some embodiments, the wiring structure includes conductive pads, conductive vias, conductive lines, conductive pillars, the like, or a combination thereof. The wiring structure may be formed of metal, such as tungsten, titanium, tantalum, ruthenium, cobalt, copper, aluminum, platinum, tin, silver, gold, the like, an alloy thereof, or a combination thereof.

The wiring structure may be disposed in dielectric layers. The dielectric layers may also be referred to as inter-metal dielectric (IMD) layers. In some embodiments, the dielectric layers may be formed of organic materials, such as a polymer base material, non-organic materials, including silicon nitride, silicon oxide, silicon oxynitride, the like, or a combination thereof.

As illustrated in FIG. 1A, a semiconductor die 104 is disposed over the substrate 102, in accordance with some embodiments. In some embodiments, the semiconductor die 104 includes a system-on-chip (SoC) die, a logic device, a memory device, a radio frequency (RF) device, the like, or any combination thereof. For example, the semiconductor die 104 may include a micro control unit (MCU) die, a microprocessor unit (MPU) die, a power management integrated circuit (PMIC) die, a radio frequency front end (RFFE) die, an accelerated processing unit (APU) die, a central processing unit (CPU) die, a graphics processing unit (GPU) die, an input-output (IO) die, a dynamic random access memory (DRAM) controller, a static random-access memory (SRAM), a high bandwidth memory (HBM), an application processor (AP) die, an application specific integrated circuit (ASIC) die, the like, or any combination thereof.

Any desired semiconductor elements (including active elements and/or passive elements) may be formed in and on the substrate 102. However, in order to simplify the figures, only the flat substrate 102 is illustrated. For example, more than one semiconductor dies and/or one or more passive components (including resistors, capacitors, or inductors) may be disposed over the substrate 102.

As illustrated in FIG. 1A, a plurality of conductive pads 106, a passivation layer 108, a plurality of bump structures 110, and a plurality of solder balls 112 are sequentially disposed on the frontside of the semiconductor die 104, in accordance with some embodiments. The conductive pads 106 may be formed of metal, such as tungsten, titanium, tantalum, ruthenium, cobalt, copper, aluminum, platinum, tin, silver, gold, the like, an alloy thereof, or a combination thereof. The edge portions of the conductive pads 106 may be covered by the passivation layer 108. The passivation layer 108 may be formed of polyimide, silicon oxide, silicon nitride, un-doped silicate glass (USG), the like, or a combination thereof.

The semiconductor die 104 may be formed over the substrate 102 and electrically coupled to the substrate 102 through the conductive pads 106, the bump structures 110, and the solder balls 112. The top portions of the bump structures 110 may be surrounded by the passivation layer 108. The bump structures 110 may be formed of metal, such as tungsten, titanium, tantalum, ruthenium, cobalt, copper, aluminum, platinum, tin, silver, gold, the like, an alloy thereof, or a combination thereof. The solder balls 112 may be formed of tin or another suitable conductive material.

As illustrated in FIG. 1A, an underfill material 114 is formed between the semiconductor die 104 and the substrate 102, in accordance with some embodiments. The underfill material 114 may surround the bump structures 110 and the solder balls 112 and may fill in gaps therebetween to provide structural support. In some embodiments, the underfill material 114 includes polymer, such as epoxy or another suitable material. The underfill material 114 may be dispensed with capillary force, and then may be cured through another suitable curing process.

Then, as illustrated in FIG. 1B, a thermal interface material 116 is disposed over the semiconductor die 104, in accordance with some embodiments. The thermal interface material 116 may be in contact with the backside of the semiconductor die 104. The thermal interface material 116 may be formed of thermal grease, thermal gel, thermal conductive adhesive, phase change material, phase change metal alloy, metal, polymer, another suitable material, or a combination thereof. The sidewalls of the thermal interface material 116 may be substantially aligned with the sidewalls of the semiconductor die 104.

Afterwards, as illustrated in FIG. 1C, an interposer 120 is mounted onto the thermal interface material 116, in accordance with some embodiments. The interposer 120 may have a wiring structure therein. In some embodiments, the wiring structure includes conductive pads, conductive vias, conductive lines, conductive pillars, the like, or a combination thereof. The wiring structure may be formed of metal, such as tungsten, titanium, tantalum, ruthenium, cobalt, copper, aluminum, platinum, tin, silver, gold, the like, an alloy thereof, or a combination thereof.

The wiring structure may be disposed in dielectric layers. The dielectric layers may also be referred to as inter-metal dielectric (IMD) layers. In some embodiments, the dielectric layers may be formed of organic materials, such as a polymer base material, non-organic materials, including silicon nitride, silicon oxide, silicon oxynitride, the like, or a combination thereof.

As illustrated in FIG. 1C, a plurality of thermal vias 121 are disposed in the interposer 120. The thermal vias 121 may extend to the bottom surface of the interposer 120 and may be in contact with the thermal interface material 116. The thermal vias 121 may vertically overlap the semiconductor die 104. As a result, the heat generated from the semiconductor die 104 may transfer to the interposer 120.

In some embodiments, the thermal vias 121 are formed of materials with high thermal conductivity, including thermal grease, thermal gel, thermal conductive adhesive, metal, polymer, another suitable material, or a combination thereof. For example, the thermal vias 121 may be formed of copper. The thermal vias 121 may be formed during the formation of the wiring structure of the interposer 120. Similar to the conductive vias 120V of the interposer 120, the thermal via 121 may have a width that decreases toward the semiconductor die 104.

The thermal vias 121 and the thermal interface material 116 may include the same material or different materials. It should be noted that the interface between the thermal vias 121 and the thermal interface material 116 may not exist if they are formed of the same material.

As illustrated in FIG. 1C, a plurality of conductive structures 118 are disposed adjacent to the semiconductor die 104 and electrically couple the substrate 102 and the interposer 120, in accordance with some embodiments. The conductive structures 118 may include solder balls or another suitable structure. The conductive structures 118 may be coupled to the thermal vias 121 through a conductive layer 120L of the interposer 120, so that addition thermal dissipation paths can be provided.

Then, a molding material 122 is formed between the substrate 102 and the interposer 120, in accordance with some embodiments. The molding material 122 may surround the semiconductor die 104, the underfill material 114, the thermal interface material 116, and the conductive structures 118 to protect these components from the environment, thereby preventing them from damage due to stress, chemicals, and moisture. The molding material 122 may be formed of a nonconductive material, including moldable polymer, epoxy, resin, the like, or a combination thereof. The sidewalls of the molding material 122 may be substantially coplanar with the sidewalls of the interposer 120 and the sidewalls of the substrate 102.

Afterwards, as illustrated in FIG. 1D, a plurality of conductive terminals 124 are disposed below the substrate 102 and electrically coupled to the wiring structure of the substrate 102, in accordance with some embodiments. The conductive terminals 124 may include microbumps, controlled collapse chip connection (C4) bumps, solder balls, ball grid array (BGA) balls, the like, or a combination thereof. The conductive terminals 124 may be formed of metal, such as nickel, lead, palladium, platinum, tin, silver, gold, the like, an alloy thereof, or a combination thereof.

One or more passive components 126 may be disposed below the substrate 102 and between the conductive terminals 124 for system performance boosted. The passive components 126 may at least partially vertically overlap the semiconductor die 104. The passive components 126 may include resistors, capacitors, or inductors. In some embodiments, the passive component 126 includes a multi-layer ceramic capacitor (MLCC). The structure shown in FIG. 1D may be referred to as a first package structure 100a.

Then, as illustrated in FIG. 1E, a second package structure 100b is stacked over the first package structure 100a, and a semiconductor package structure 100 is formed, in accordance with some embodiments.

The second package structure 100b includes a package substrate 130, in accordance with some embodiments. The package substrate 130 may have a wiring structure therein. In some embodiments, the wiring structure of the package substrate 130 includes conductive layers, conductive vias, conductive pillars, the like, or a combination thereof. The wiring structure of the package substrate 130 may be similar to the wiring structure of the substrate 102, and will not be repeated.

The second package structure 100b includes a plurality of conductive terminals 128 disposed below the package substrate 130 and electrically coupled to the interposer 120, in accordance with some embodiments. The conductive terminals 128 may include microbumps, controlled collapse chip connection (C4) bumps, solder balls, ball grid array (BGA) balls, the like, or a combination thereof. The conductive terminals 128 may be formed of metal, such as nickel, lead, palladium, platinum, tin, silver, gold, the like, an alloy thereof, or a combination thereof.

The second package structure 100b includes one or more semiconductor dies 132 disposed over the package substrate 130, in accordance with some embodiments. The number of the semiconductor dies 132 shown in the figures are exemplary only and are not intended to limit the present disclosure. The semiconductor dies 132 may include the same or different devices. For example, the semiconductor dies 132 may include memory dies, such as a dynamic random access memory (DRAM), or another suitable device. The semiconductor dies 132 may be electrically coupled to the package substrate 130 through a plurality of bonding wires.

The second package structure 100b may also include one or more passive components (not illustrated) over the package substrate 130, including resistors, capacitors, or inductors.

The package structure 100b includes a molding material 134 disposed over the package substrate 130 and surrounding the semiconductor dies 132 and the bonding wires, in accordance with some embodiments. The molding material 134 may protect the semiconductor dies 132 and the bonding wires from the environment, thereby preventing these components from damage due to stress, chemicals, and moisture. The molding material 134 may be formed of a nonconductive material, including moldable polymer, epoxy, resin, the like, or a combination thereof.

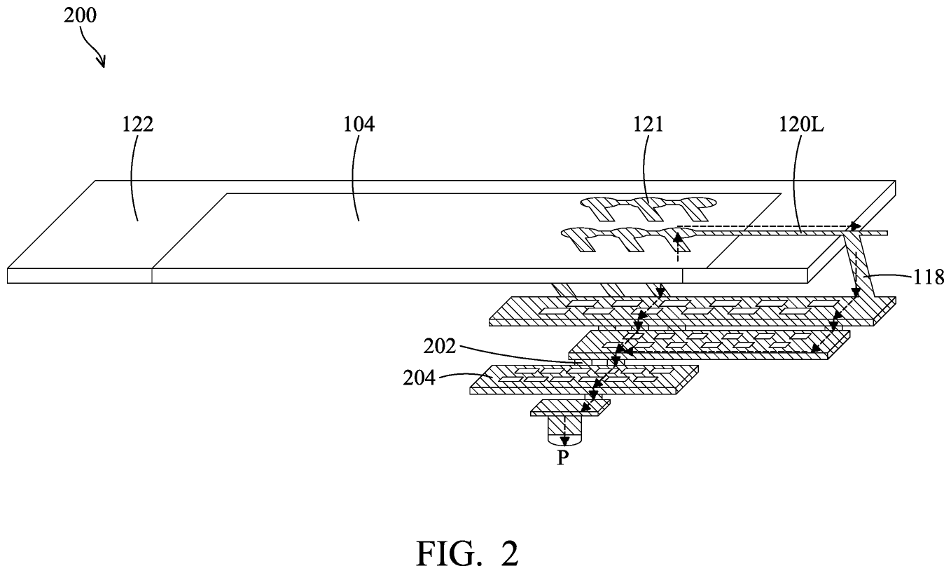

FIG. 2 is a perspective view of a portion 200 of the semiconductor package structure 100 of FIG. 1, in accordance with some embodiments. The portion of the semiconductor package structure in FIG. 2 may include the same or similar components as that of the semiconductor package structure 100 in FIG. 1, and for the sake of simplicity, those components will not be discussed in detail again.

As illustrated in FIG. 2, the thermal vias 121 may be disposed directly above the semiconductor die 104. The location and the arrangement of the thermal vias 121 are adjustable. For example, the thermal vias 121 may be disposed on hot spot, such as over the core area of the semiconductor die 104.

As indicated by the path P, the heat from the semiconductor die 104 may be transferred upward to the interposer 120 (as shown in FIG. 1E) through the thermal vias 121 and may be transferred to the conductive structures 118 through the conductive layer 120L of the interposer 120. In addition, the heat from the semiconductor die 104 and from the conductive structures 118 may be transferred downward to the substrate 102 (as shown in FIG. 1E).

As illustrated in FIG. 2, the substrate 102 may include a plurality of dummy metal layers 204 to meet the metal density and uniformity requirement. The semiconductor package structure may include a plurality of thermal vias 202 embedded in the substrate 102 to connect the dummy metal layers 204, so that the efficiency of thermal dissipation can be improved. The thermal vias 202 may be formed during the formation of the substrate 102. The thermal vias 202 may be similar to the thermal vias 121, and will not be repeated.

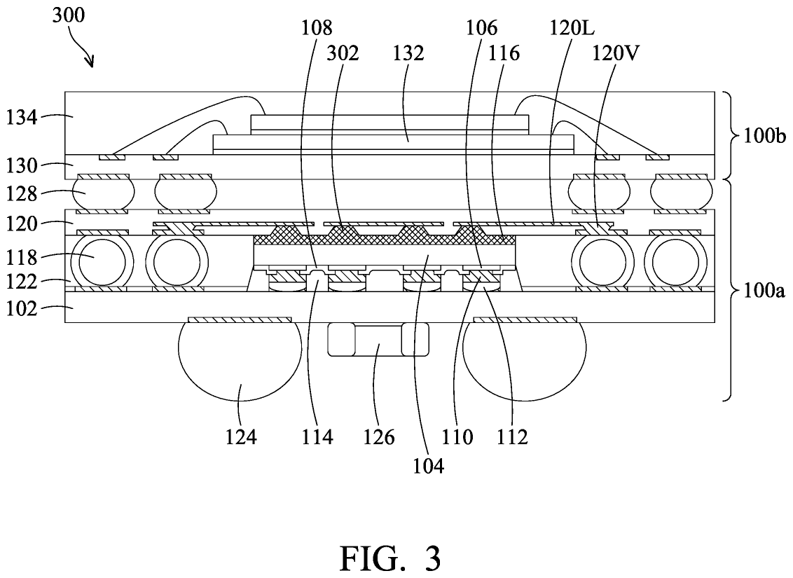

FIG. 3 is a cross-sectional view of a semiconductor package structure 300 in accordance with some embodiments of the disclosure. It should be noted that the semiconductor package structure 300 may include the same or similar components as that of the semiconductor package structure 100, which is illustrated in FIG. 1E, and for the sake of simplicity, those components will not be discussed in detail again. In the following embodiments, the width of the thermal via increases toward the semiconductor die.

According to some embodiments, the semiconductor package structure 300 includes a plurality of thermal vias 302, which are formed after the formation of the interposer 120. In particular, openings (not illustrated) for the thermal vias 302 may be formed during the formation of the interposer 120. Then, when the interposer 120 is mounted onto the substrate 102, the thermal interface material 116 may be filled into the openings of the thermal vias 302. The thermal interface material 116 may be formed of a flowable material, including thermal grease, thermal gel, thermal conductive adhesive, polymer, another suitable material, or a combination thereof.

As illustrated in FIG. 3, the width of each of the thermal vias 302 may increase toward the semiconductor die 104 to help fill the thermal interface material 116 into the openings. In particular, the shapes of the thermal vias 302 may be different from the shapes of the conductive vias 120V of the interposer 120, which may each have a width that decreases toward the semiconductor die 104.

In these embodiments, the interface between the thermal vias 302 and the thermal interface material 116 is not present. That is, the thermal interface material 116 extends from the interior of the interposer 120 to the top surface of the semiconductor die 104, and may extend further to the sidewalls of the semiconductor die 104.

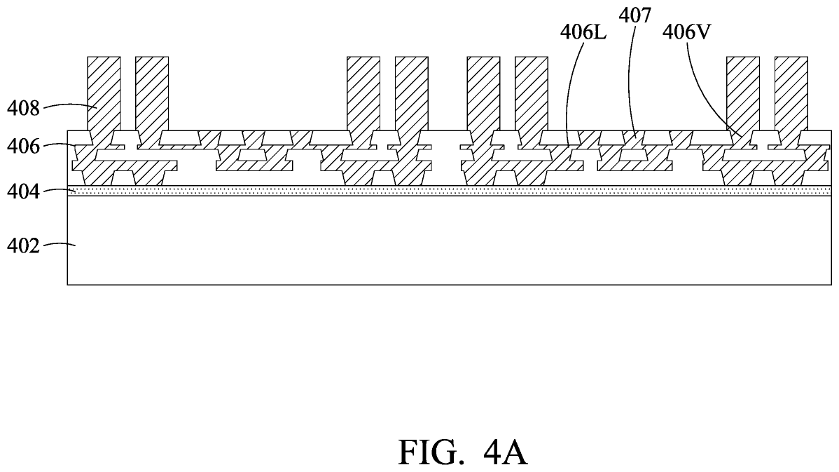

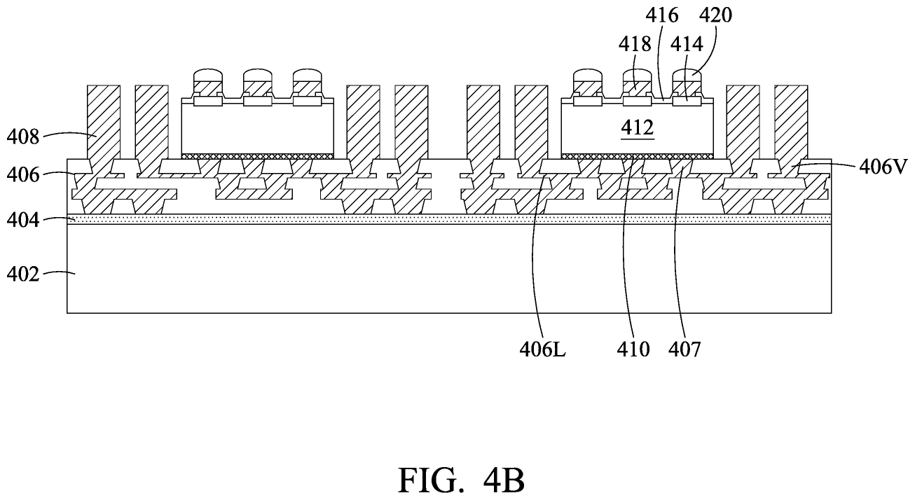

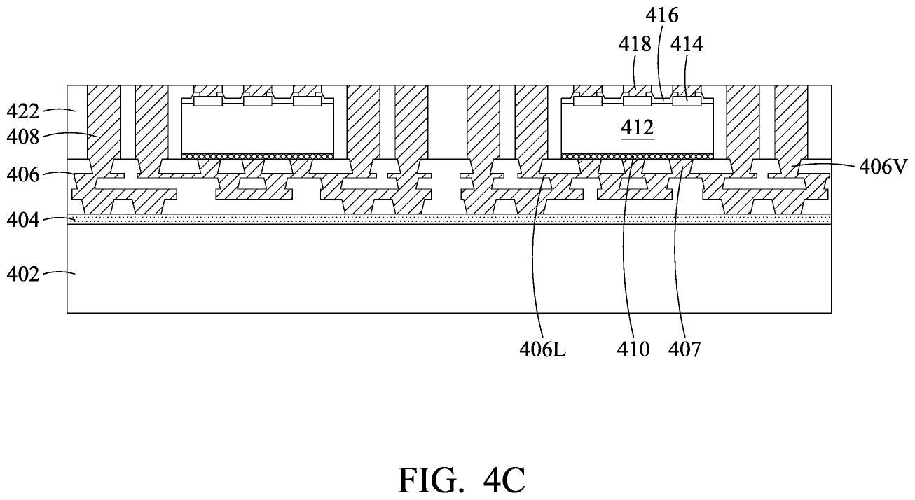

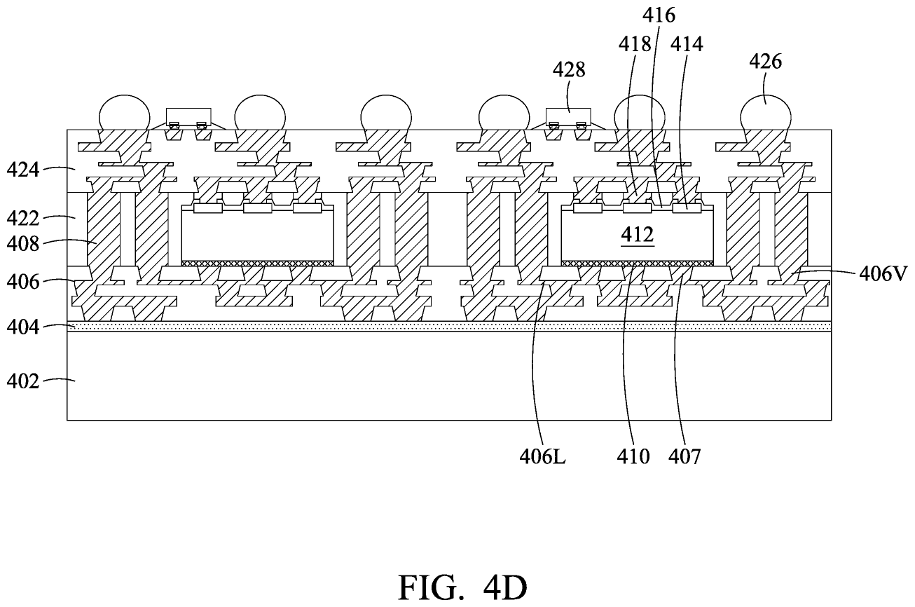

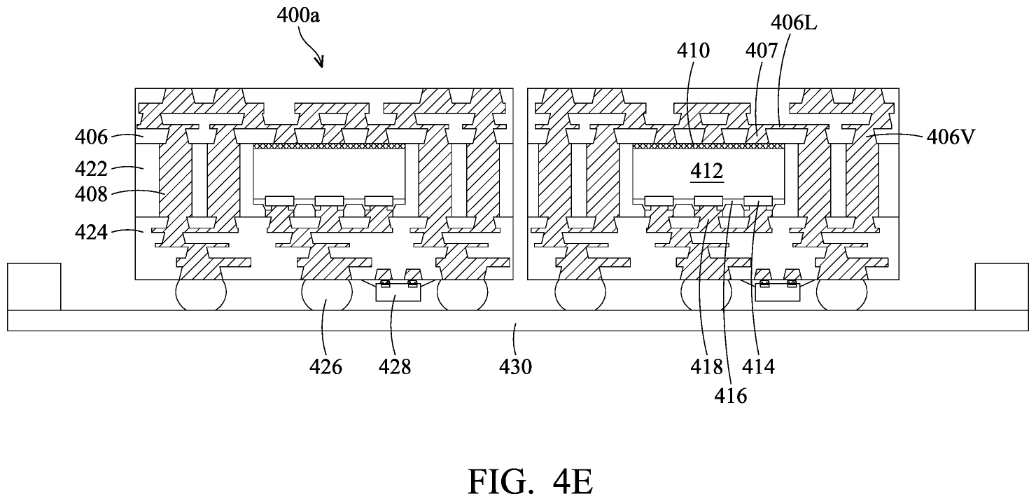

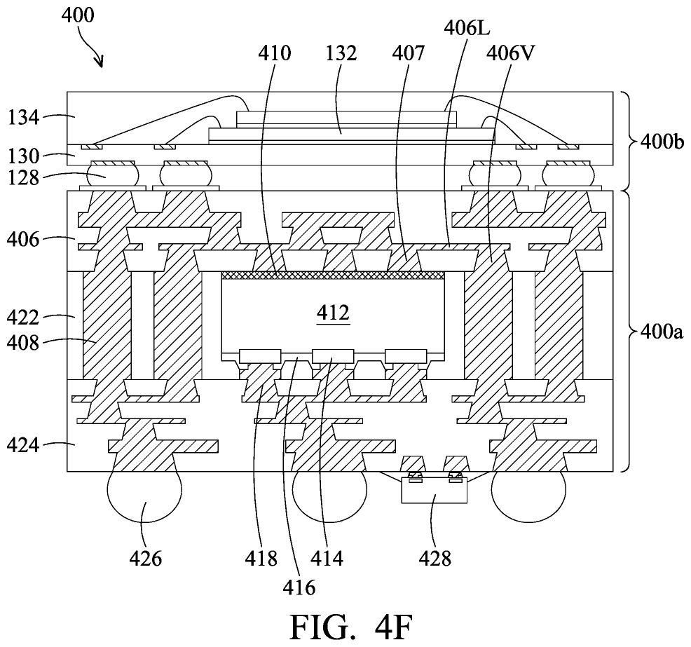

FIGS. 4A-4E are cross-sectional views of various stages of manufacturing a semiconductor package structure 400 in accordance with some embodiments of the present disclosure. Additional features can be added to the semiconductor package structure 400. Some of the features described below can be replaced or eliminated for different embodiments. To simplify the diagram, only a portion of the semiconductor package structure 400 is illustrated. In the following embodiments, an integrated fan-out (InFO) package-on-package (POP) structure is described.

As illustrated in FIG. 4A, an adhesive layer 404 is formed over a carrier wafer 402, in accordance with some embodiments. The carrier wafer 402 may be a glass carrier substrate, a ceramic carrier substrate, or another suitable carrier substrate. The adhesive layer 404 may be formed of polymer, and may be removed along with the carrier wafer 402 from the structure formed thereon when heated or exposed to UV light.

Then, a redistribution layer 406 and a plurality of thermal vias 407 are formed over the adhesive layer 404, in accordance with some embodiments. The redistribution layer 406 may include conductive layers disposed in passivation layers. The conductive layers may be formed of metal, such as tungsten, titanium, tantalum, ruthenium, cobalt, copper, aluminum, platinum, tin, silver, gold, the like, an alloy thereof, or a combination thereof. The passivation layers may include polymer layers, which may be formed of polyimide (PI), polybenzoxazole (PBO), benzocyclobutene (BCB), epoxy, the like, or a combination thereof. Alternatively, the passivation layers may include dielectric layers, which may be formed of silicon oxide, silicon nitride, silicon oxynitride, the like, or a combination thereof.

In some embodiments, the thermal vias 407 are formed during the formation of the conductive layers of the redistribution layer 406. The thermal vias 407 may be formed of material with high thermal conductivity, including metal, polymer, another suitable material, or a combination thereof. The thermal vias 407 may be surrounded by the passivation layers, and the top surface of the thermal vias 407 may be exposed.

Afterwards, a plurality of conductive pillars 408 are formed over the redistribution layer 406 and on opposite sides of the thermal vias 407, in accordance with some embodiments. The conductive pillars 408 may be formed of metal, such as tungsten, titanium, tantalum, ruthenium, cobalt, copper, aluminum, platinum, tin, silver, gold, the like, an alloy thereof, or a combination thereof. The redistribution layer 406 may include a conductive line 406L which couples the conductive pillars 408 and the thermal vias 407 to provide additional thermal dissipation paths.

Then, as illustrated in FIG. 4B, a thermal interface material 410 is disposed over the redistribution layer 406 and in contact with the thermal vias 407, in accordance with some embodiments. The thermal interface material 410 may be formed of metal, polymer, another suitable material, or a combination thereof. The thermal vias 407 and the thermal interface material 410 may include the same material or different materials. The interface between the thermal vias 407 and the thermal interface material 410 may not exist if they are formed of the same material.

A semiconductor die 412 is disposed over the thermal interface material 410, in accordance with some embodiments. In some embodiments, the semiconductor die 412 includes a system-on-chip (SoC) die, a logic device, a memory device, a radio frequency (RF) device, the like, or any combination thereof. For example, the semiconductor die 412 may include a micro control unit (MCU) die, a microprocessor unit (MPU) die, a power management integrated circuit (PMIC) die, a radio frequency front end (RFFE) die, an accelerated processing unit (APU) die, a central processing unit (CPU) die, a graphics processing unit (GPU) die, an input-output (IO) die, a dynamic random access memory (DRAM) controller, a static random-access memory (SRAM), a high bandwidth memory (HBM), an application processor (AP) die, an application specific integrated circuit (ASIC) die, the like, or any combination thereof. Additional semiconductor dies and/or one or more passive components (including resistors, capacitors, or inductors) may be disposed over the redistribution layer 424.

As illustrated in FIG. 4B, the backside of the semiconductor die 412 may be in contact with the thermal interface material 410, and the frontside of the semiconductor die 412 may be away from the thermal interface material 410. The sidewalls of the thermal interface material 410 may be substantially aligned with the sidewalls of the semiconductor die 412.

A plurality of conductive pads 414, a passivation layer 416, a plurality of bump structures 418, and a plurality of solder balls 420 are sequentially disposed over the frontside of the semiconductor die 412, in accordance with some embodiments. The passivation layer 416 may cover edge portions of the conductive pads 414 and surround the bottom portions of the bump structures 418. The conductive pads 414, the passivation layer 416, the bump structures 418, and the solder balls 420 may be similar to the conductive pads 106, the passivation layer 108, the bump structures 110, and the solder balls 112 as illustrated in FIG. 1A, respectively, and will not be repeated.

Afterwards, as illustrated in FIG. 4C, a molding material 422 is formed over the redistribution layer 406, in accordance with some embodiments. The molding material 422 may surround the semiconductor die 412, the bump structures 418, the thermal interface material 410, and the conductive pillars 408 to protect these components from the environment, thereby preventing them from damage due to stress, chemicals, and moisture. The molding material 422 may be formed of a nonconductive material, including moldable polymer, epoxy, resin, the like, or a combination thereof.

Then, the solder balls 420 and the top portions of the molding material 422 and the conductive pillars 408 may be removed by a planarization process, such as a chemical mechanical polish (CMP) process, a mechanical grinding process, or the like.

Afterwards, as illustrated in FIG. 4D, a redistribution layer 424 is formed over the molding material 422 and the conductive pillars 408, in accordance with some embodiments. The redistribution layer 424 may include conductive layers disposed in passivation layers. The conductive layers may be formed of metal, such as tungsten, titanium, tantalum, ruthenium, cobalt, copper, aluminum, platinum, tin, silver, gold, the like, an alloy thereof, or a combination thereof. The passivation layers may include polymer layers, which may be formed of polyimide (PI), polybenzoxazole (PBO), benzocyclobutene (BCB), epoxy, the like, or a combination thereof. Alternatively, the passivation layers may include dielectric layers, which may be formed of silicon oxide, silicon nitride, silicon oxynitride, the like, or a combination thereof. The semiconductor die 412 may be electrically coupled to the redistribution layer 424 through the conductive pads 414 and the bump structures 418.

Then, a plurality of conductive terminals 426 are disposed over and electrically coupled to the redistribution layer 424, in accordance with some embodiments. The conductive terminals 426 may include microbumps, controlled collapse chip connection (C4) bumps, solder balls, ball grid array (BGA) balls, the like, or a combination thereof. The conductive terminals 426 may be formed of metal, such as nickel, lead, palladium, platinum, tin, silver, gold, the like, an alloy thereof, or a combination thereof.

One or more passive components 428 may be disposed over the redistribution layer 424 and between the conductive terminals 426 for system performance boosted. As illustrated in FIG. 4D, the passive components 428 may at least partially vertically overlap the semiconductor die 412. The passive components 428 may include resistors, capacitors, or inductors. In some embodiments, the passive components 428 include an integrated passive device (IPD).

Afterwards, as illustrated in FIG. 4E, the structure shown in FIG. 4D is attached to a frame 430 and the carrier wafer 402 is removed, in accordance with some embodiments. The frame 430 may include a tape frame or another suitable frame that can provide support during a singulation process. The structure may be sawed into first package structures 400a by sawing along scribe lines between the first package structures 400a in the singulation process. Then, the frame 430 may be removed.

Afterwards, as illustrated in FIG. 4F, a second package structure 400b is stacked over the first package structure 400a, and a semiconductor package structure 400 is formed, in accordance with some embodiments. The second package structure 400b may be similar to the second package structure 100b as illustrated in FIG. 1E, and will not be repeated.

Similar to the previous description with reference to FIG. 2, the semiconductor package structure 400 may include a plurality of dummy metal layers (not illustrated) and a plurality of thermal vias (not illustrated) to connect the dummy metal layers in the redistribution layer 424 to improve the efficiency of thermal dissipation. These thermal vias may be formed during the formation of the redistribution layer 424 and may be similar to the thermal vias 407, and will not be repeated.

By disposing the thermal vias 407 vertically overlap the semiconductor die 412, the heat from the semiconductor die 412 can be transferred to the redistribution layer 406. In addition, the thermal vias 407 may be coupled to the conductive pillars 408 through a conductive layer 406L of the redistribution layer 406 to provide addition thermal dissipation paths.

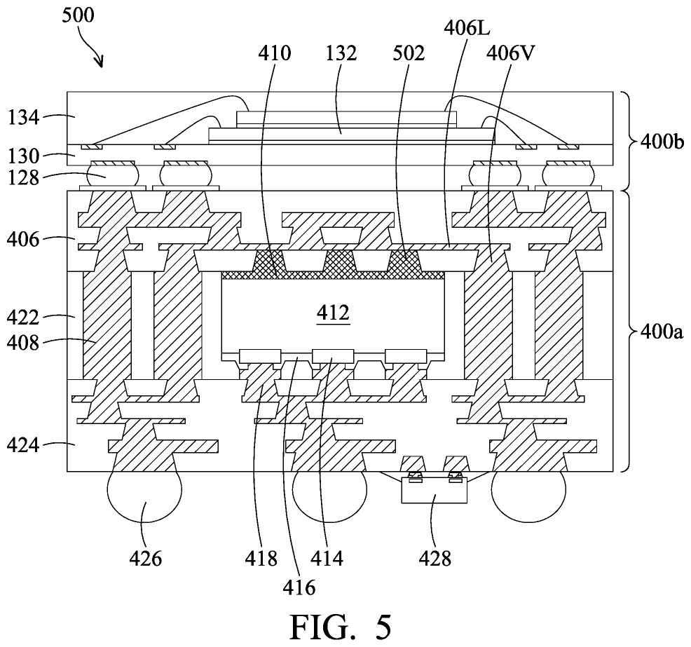

FIG. 5 is a cross-sectional view of a semiconductor package structure 500 in accordance with some embodiments of the disclosure. It should be noted that the semiconductor package structure 500 may include the same or similar components as that of the semiconductor package structure 400, which is illustrated in FIG. 4F, and for the sake of simplicity, those components will not be discussed in detail again. In the following embodiments, the thermal vias are formed during the formation of the thermal interface material.

According to some embodiments, openings (not illustrated) for the thermal vias 502 are formed during the formation of the redistribution layer 406. Then, during the formation of the thermal interface material 410, the thermal interface material 410 may fill the openings of the thermal vias 502. The width of each of the thermal vias 502 increases toward the semiconductor die 412, which helps to fill the thermal interface material 410 into the openings.

The thermal interface material 410 may be formed of a flowable material, including thermal grease, thermal gel, thermal conductive adhesive, polymer, another suitable material, or a combination thereof. In particular, the thermal interface material 410 extends from the interior of the redistribution layer 406 to the top surface of the semiconductor die 412, and it may extend further to the sidewalls of the semiconductor die 412.

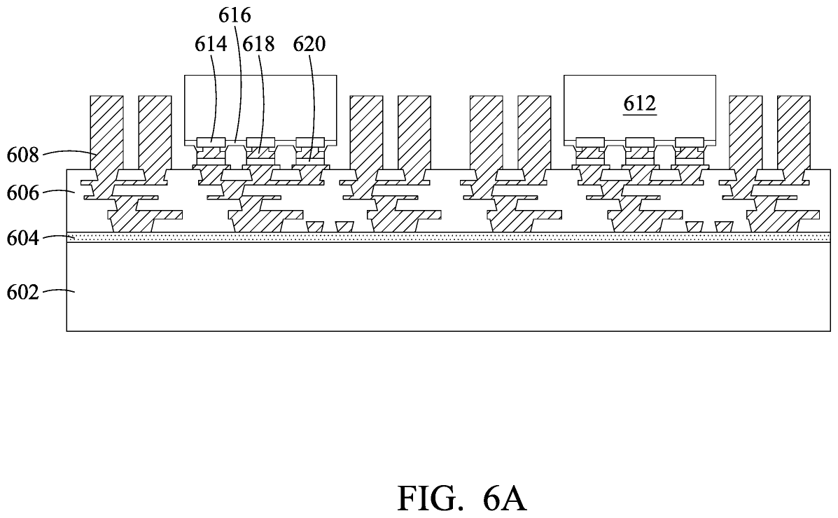

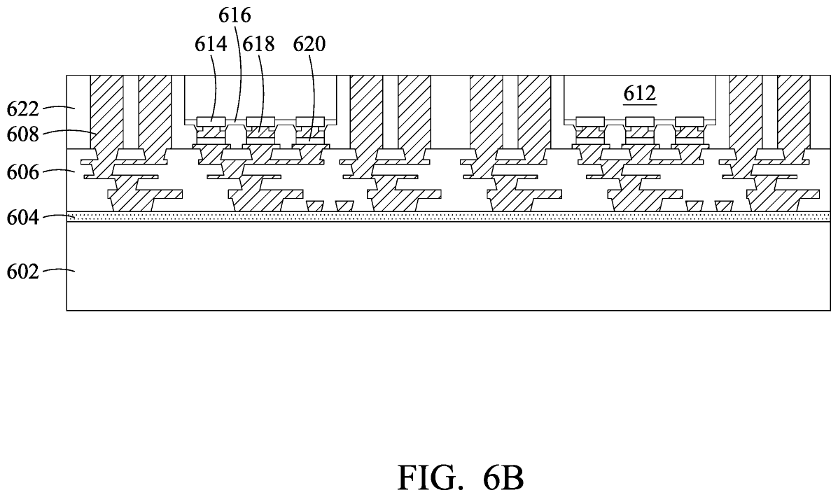

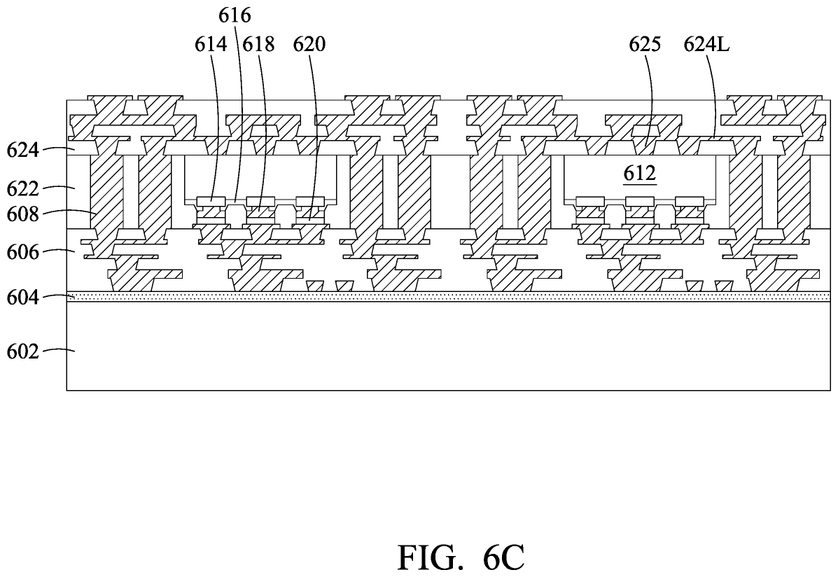

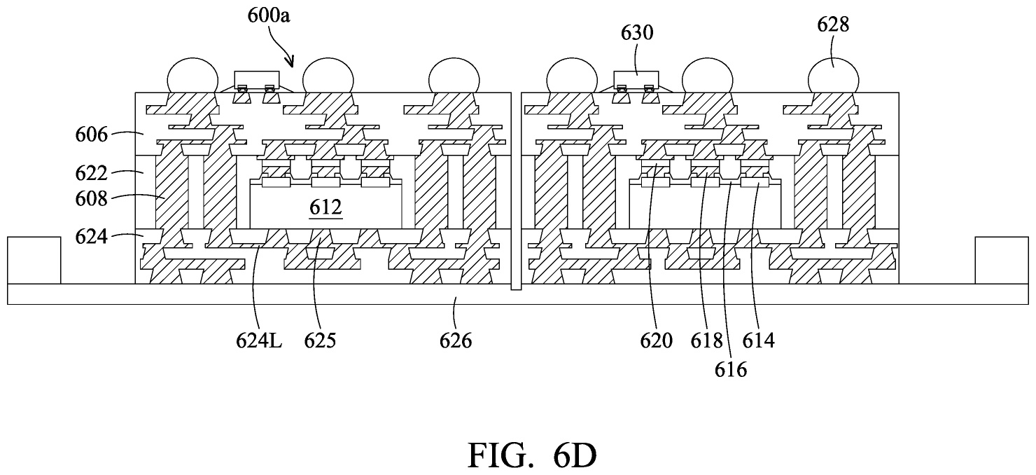

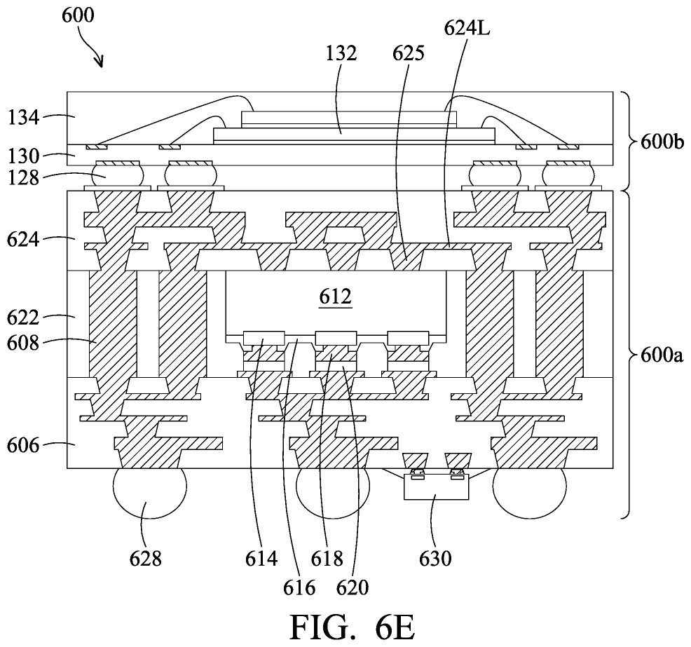

FIGS. 6A-6E are cross-sectional views of various stages of manufacturing a semiconductor package structure 600 in accordance with some embodiments of the present disclosure. Additional features can be added to the semiconductor package structure 600. Some of the features described below can be replaced or eliminated for different embodiments. To simplify the diagram, only a portion of the semiconductor package structure 600 is illustrated. In the following embodiments, the thermal vias are in contact with the semiconductor die.

As illustrated in FIG. 6A, an adhesive layer 604 is formed over a carrier wafer 602, in accordance with some embodiments. The carrier wafer 602 may be a glass carrier substrate, a ceramic carrier substrate, or another suitable carrier substrate. The adhesive layer 604 may be formed of polymer, and may be removed along with the carrier wafer 602 from the structure formed thereon when heated or exposed to UV light.

Then, a redistribution layer 606 is formed over the adhesive layer 604, in accordance with some embodiments. The redistribution layer 606 may include conductive layers disposed in passivation layers. The conductive layers may be formed of metal, such as tungsten, titanium, tantalum, ruthenium, cobalt, copper, aluminum, platinum, tin, silver, gold, the like, an alloy thereof, or a combination thereof. The passivation layers may include polymer layers, which may be formed of polyimide (PI), polybenzoxazole (PBO), benzocyclobutene (BCB), epoxy, the like, or a combination thereof. Alternatively, the passivation layers may include dielectric layers, which may be formed of silicon oxide, silicon nitride, silicon oxynitride, the like, or a combination thereof.

Afterwards, a plurality of conductive pillars 608 are formed over the redistribution layer 606, in accordance with some embodiments. The conductive pillars 608 may be similar to the conductive pillars 408 as illustrated in FIG. 4A, and will not be repeated.

A semiconductor die 612 is disposed over the redistribution layer 606, in accordance with some embodiments. In some embodiments, the semiconductor die 612 includes a system-on-chip (SoC) die, a logic device, a memory device, a radio frequency (RF) device, the like, or any combination thereof. For example, the semiconductor die 612 may include a micro control unit (MCU) die, a microprocessor unit (MPU) die, a power management integrated circuit (PMIC) die, a radio frequency front end (RFFE) die, an accelerated processing unit (APU) die, a central processing unit (CPU) die, a graphics processing unit (GPU) die, an input-output (IO) die, a dynamic random access memory (DRAM) controller, a static random-access memory (SRAM), a high bandwidth memory (HBM), an application processor (AP) die, an application specific integrated circuit (ASIC) die, the like, or any combination thereof. Additional semiconductor dies and/or one or more passive components (including resistors, capacitors, or inductors) may be disposed over the redistribution layer 606.

A plurality of conductive pads 614, a passivation layer 616, a plurality of bump structures 618, and a plurality of solder balls 620 are sequentially disposed over the frontside of the semiconductor die 612, in accordance with some embodiments. The passivation layer 616 may cover edge portions of the conductive pads 614 and surround the top portions of the bump structures 618.

The semiconductor die 612 may be formed over the redistribution layer 606 and electrically coupled to the redistribution layer 606 through the conductive pads 614, the bump structures 618, and the solder balls 620. The conductive pads 614, the passivation layer 616, the bump structures 618, and the solder balls 620 may be similar to the conductive pads 106, the passivation layer 108, the bump structures 110, and the solder balls 112 as illustrated in FIG. 1A, respectively, and will not be repeated.

Afterwards, as illustrated in FIG. 6B, a molding material 622 is formed over the redistribution layer 606, in accordance with some embodiments. The molding material 622 may surround the semiconductor die 612, the bump structures 618, and the conductive pillars 608 to protect these components from the environment, thereby preventing them from damage due to stress, chemicals, and moisture. The molding material 622 may be formed of a nonconductive material, including moldable polymer, epoxy, resin, the like, or a combination thereof.

Then, the top portions of the molding material 622, and the conductive pillars 608, and the semiconductor die 612 may be removed by a planarization process, such as a chemical mechanical polish (CMP) process, a mechanical grinding process, or the like.

Afterwards, as illustrated in FIG. 6C, a redistribution layer 624 and a plurality of thermal vias 625 are formed over the molding material 622 and the conductive pillars 608, in accordance with some embodiments. The redistribution layer 624 may include conductive layers disposed in passivation layers. The conductive layers and the passivation layers of the redistribution layer 624 may be similar to that of the redistribution layer 606, and will not be repeated.

In some embodiments, the thermal vias 625 are formed during the formation of the conductive layers of the redistribution layer 624. The thermal vias 625 may be formed of material with high thermal conductivity, including metal, polymer, another suitable material, or a combination thereof. The thermal vias 625 may be surrounded by the passivation layers. The thermal vias 625 may be in contact with the backside of the semiconductor die 612, and may be away from the frontside of the semiconductor die 612. The redistribution layer 624 may include a conductive line 624L which couples the conductive pillars 608 and the thermal vias 625 to provide additional thermal dissipation paths.

Afterwards, as illustrated in FIG. 6D, the structure shown in FIG. 6C is attached to a frame 626 and the carrier wafer 602 is removed, in accordance with some embodiments. The frame 626 may include a tape frame or another suitable frame that can provide support during a singulation process.

Then, a plurality of conductive terminals 628 are disposed over and electrically coupled to the redistribution layer 606, in accordance with some embodiments. The conductive terminals 628 may be similar to the conductive terminals 426, and will not be repeated.

One or more passive components 630 may be disposed over the redistribution layer 606 and between the conductive terminals 628 for system performance boosted. As illustrated in FIG. 6D, the passive components 630 may at least partially vertically overlap the semiconductor die 612. The passive components 630 may include resistors, capacitors, or inductors. In some embodiments, the passive components 630 include an integrated passive device (IPD).

Afterwards, the structure may be sawed into first package structures 600a by sawing along scribe lines between the first package structures 600a in the singulation process. Then, the frame 626 may be removed.

Afterwards, as illustrated in FIG. 6E, a second package structure 600b is stacked over the first package structure 600a, and a semiconductor package structure 600 is formed, in accordance with some embodiments. The second package structure 600b may be similar to the second package structure 100b as illustrated in FIG. 1E, and will not be repeated.

Similar to the previous description with reference to FIG. 2, the semiconductor package structure 600 may include a plurality of dummy metal layers (not illustrated) and a plurality of thermal vias (not illustrated) to connect the dummy metal layers in the redistribution layer 606 to improve the efficiency of thermal dissipation. These thermal vias may be formed during the formation of the redistribution layer 606 and may be similar to the thermal vias 625, and will not be repeated.

By disposing the thermal vias 625 vertically overlapping and in contact with the semiconductor die 612, the heat from the semiconductor die 612 can be transferred to the redistribution layer 624. In addition, the thermal vias 625 may be coupled to the conductive pillars 608 through a conductive layer 624L of the redistribution layer 624 to provide addition thermal dissipation paths.

In summary, the semiconductor package structure according to the present disclosure includes a plurality of thermal vias vertically overlapping a semiconductor die to enhance the efficiency of thermal dissipation. The thermal vias may be formed in a redistribution layer or an interposer to leverage current process and keep original height of the semiconductor package structure.

In addition, the thermal vias may be coupled to conductive pillars or conductive structures through conductive lines in the redistribution layer or the interposer to increase the number of thermal dissipation paths. Furthermore, additional thermal vias may be disposed in a substrate or a redistribution layer to connect the dummy metal layers therein to further improve the efficiency of thermal dissipation.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package structure, comprising:
a substrate having a wiring structure;
a semiconductor die disposed over the substrate and electrically coupled to the wiring structure;
a molding material surrounding the semiconductor die;
an interposer disposed over the semiconductor die; and
a thermal via disposed in the interposer and extending to a bottom surface of the interposer, wherein the thermal via vertically overlaps the semiconductor die.

2. The semiconductor package structure as claimed in claim 1, wherein the thermal via comprises metal, polymer, or a combination thereof.

3. The semiconductor package structure as claimed in claim 1, further comprising a thermal interface material connecting the thermal via and the semiconductor die and surrounded by the molding material.

4. The semiconductor package structure as claimed in claim 3, wherein the thermal interface material comprises metal, polymer, or a combination thereof.

5. The semiconductor package structure as claimed in claim 4, wherein the thermal via and the thermal interface material comprise a same material.

6. The semiconductor package structure as claimed in claim 1, further comprising a plurality of conductive structures electrically coupling the interposer to the substrate on opposite sides of the semiconductor die and surrounded by the molding material.

7. The semiconductor package structure as claimed in claim 6, wherein the interposer comprises a conductive layer coupling the thermal via to one of the conductive structures.

8. The semiconductor package structure as claimed in claim 1, wherein a width of the thermal via increases in a direction toward the semiconductor die.

9. A semiconductor package structure, comprising:
a first redistribution layer;
a semiconductor die disposed over the first redistribution layer;
a second redistribution layer disposed over the semiconductor die; and
a thermal via disposed in the second redistribution layer and extending to a bottom surface of the second redistribution layer, wherein the thermal via vertically overlaps the semiconductor die.

10. The semiconductor package structure as claimed in claim 9, further comprising a thermal interface material in contact with the thermal via and the semiconductor die.

11. The semiconductor package structure as claimed in claim 10, wherein the thermal interface material comprises metal, polymer, or a combination thereof.

12. The semiconductor package structure as claimed in claim 10, wherein the thermal via and the thermal interface material comprise a same material.

13. The semiconductor package structure as claimed in claim 10, wherein a sidewall of the thermal interface material is substantially aligned with a sidewall of the semiconductor die.

14. The semiconductor package structure as claimed in claim 9, wherein the thermal via is in contact with a backside of the semiconductor die.

15. The semiconductor package structure as claimed in claim 9, further comprising a plurality of conductive pillars between the second redistribution layer and the first redistribution layer.

16. The semiconductor package structure as claimed in claim 15, wherein the second redistribution layer comprises a conductive layer coupling the thermal via to one of the conductive pillars.

17. A semiconductor package structure, comprising:
a first redistribution layer;
a semiconductor die disposed over the first redistribution layer;
a bump structure electrically coupling the semiconductor die to the first redistribution layer;
a second redistribution layer disposed over the semiconductor die; and
a plurality of thermal vias embedded in the second redistribution layer and in contact with the semiconductor die.

18. The semiconductor package structure as claimed in claim 17, wherein the thermal vias comprise metal, polymer, or a combination thereof.

19. The semiconductor package structure as claimed in claim 17, further comprising a conductive pillar adjacent to the semiconductor die and coupled to one of the thermal vias through a conductive layer of the second redistribution layer.

20. The semiconductor package structure as claimed in claim 19, further comprising a molding material surrounding the semiconductor die, the conductive structure, and the conductive pillar.
